(19) United States
(12) Patent Application Publication
(10) Pub. No.: US 2026/0191078 A1
(43) Pub. Date: Jul. 2, 2026

(54) SEMICONDUCTOR DEVICE AND METHOD FOR MANUFACTURING SEMICONDUCTOR DEVICE

(71) Applicant: ROHM CO., LTD., Kyoto-shi (JP)

(72) Inventor: Oji SATO, Kyoto-shi (JP)

(21) Appl. No.: 19/544,647

(22) Filed: Feb. 19, 2026

Related U.S. Application Data
(63) Continuation of application No. PCT/JP2024/028462, filed on Aug. 8, 2024.

(30) Foreign Application Priority Data
Aug. 31, 2023 (JP) 2023-140812

(51) Int. Cl. H10W 72/50; H10D 80/20; H10W 72/00

(52) U.S. Cl. CPC H10W 72/5449; H10D 80/251; H10W 72/015

(57) ABSTRACT

A semiconductor device includes a support, a first semiconductor element supported on the support, and a first bonding sheet interposed between the support and the first semiconductor element. The first bonding sheet includes a first portion and a second portion. The first portion includes a part that overlaps with the first semiconductor element as viewed in the thickness direction of the support. The second portion includes a part that does not overlap with the first semiconductor element as viewed in the thickness direction. The second portion is smaller in thickness in the thickness direction than the first portion.

### TECHNICAL FIELD

The present disclosure relates to a semiconductor device and a method for manufacturing the semiconductor device.

### BACKGROUND ART

An example of a conventional semiconductor device is disclosed in JP-A-2022-63488. The semiconductor device disclosed in JP-A-2022-63488 includes a support substrate and a semiconductor element. The semiconductor element is bonded by solid-phase diffusion bonding via an intermediate metal layer.

### BRIEF DESCRIPTION OF THE DRAWINGS

FIG. 1 is a plan view showing a semiconductor device according to a first embodiment of the present disclosure.

FIG. 2 is a partial plan view showing the semiconductor device according to the first embodiment of the present disclosure.

FIG. 3 is a sectional view taken along line III-III in FIG. 2.

FIG. 4 is a partial enlarged plan view showing the semiconductor device according to the first embodiment of the present disclosure.

FIG. 5 is a partial enlarged sectional view taken along line V-V in FIG. 4.

FIG. 6 is a partial enlarged plan view showing the semiconductor device according to the first embodiment of the present disclosure.

FIG. 7 is a partial enlarged sectional view taken along line VII-VII in FIG. 6.

FIG. 8 is a system configuration diagram showing a vehicle equipped with the semiconductor device according to the first embodiment of the present disclosure.

FIG. 9 is a perspective view showing a holder used in a manufacturing method of the semiconductor device according to the first embodiment of the present disclosure.

FIG. 10 is a bottom view showing the holder used in the manufacturing method of the semiconductor device according to the first embodiment of the present disclosure.

FIG. 11 is a sectional view taken along line XI-XI in FIG. 10.

FIG. 12 is a sectional view taken along line XI-XI in FIG. 10.

FIG. 13 is a partially enlarged sectional view showing the holder used in the manufacturing method of the semiconductor device according to the first embodiment of the present disclosure.

FIG. 14 is a plan view showing the manufacturing method of the semiconductor device according to the first embodiment of the present disclosure.

FIG. 15 is a sectional view taken along line XV-XV in FIG. 14.

FIG. 16 is a partial enlarged plan view showing a first variation of the semiconductor device according to the first embodiment of the present disclosure.

FIG. 17 is a partial enlarged plan view showing a second variation of the semiconductor device according to the first embodiment of the present disclosure.

FIG. 18 is a partial enlarged plan view showing a third variation of the semiconductor device according to the first embodiment of the present disclosure.

FIG. 19 is a partial enlarged plan view showing a semiconductor device according to a second embodiment of the present disclosure.

FIG. 20 is a partial enlarged plan view showing a first variation of the semiconductor device according to the second embodiment of the present disclosure.

FIG. 21 is a partial enlarged plan view showing a semiconductor device according to a third embodiment of the present disclosure.

FIG. 22 is a partial enlarged sectional view taken along line XXII-XXII in FIG. 21.

FIG. 23 is a partial enlarged plan view showing a first variation of the semiconductor device according to the third embodiment of the present disclosure.

FIG. 24 is a partial enlarged sectional view taken along line XXIV-XXIV in FIG. 23.

FIG. 25 is a perspective view showing another example of the holder used in the manufacturing method of the semiconductor device of the present disclosure.

FIG. 26 is a sectional view showing another example of the holder used in the manufacturing method of the semiconductor device of the present disclosure.

### DETAILED DESCRIPTION OF EMBODIMENTS

The following describes preferred embodiments of the present disclosure in detail with reference to the drawings.

In the present disclosure, the terms such as "first", "second", and "third" are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

### First embodiment:

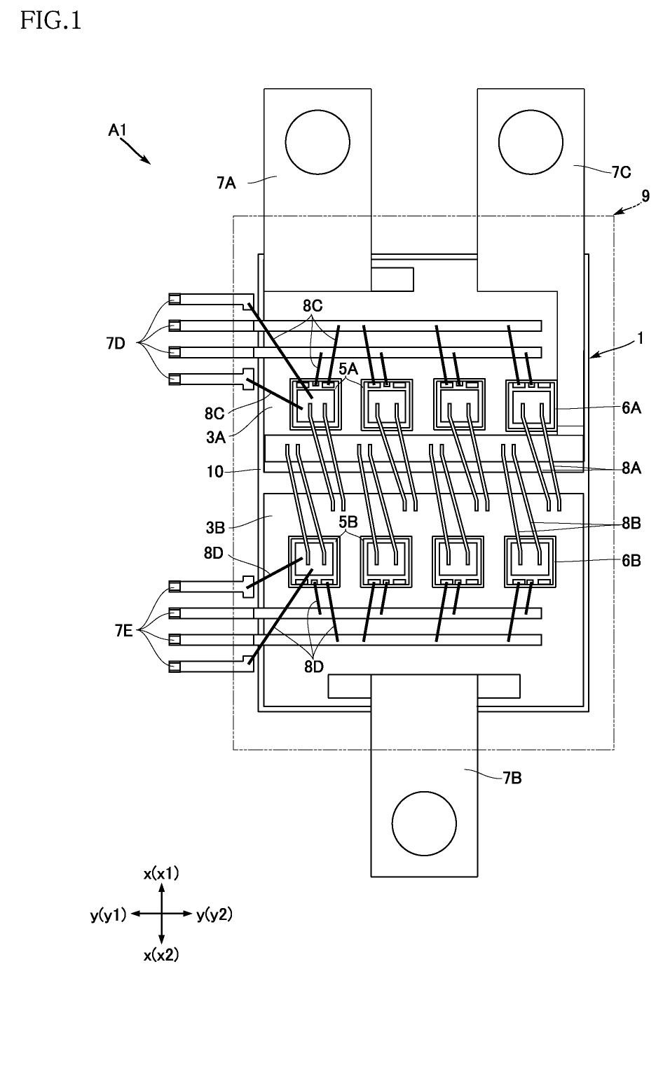

FIGS. 1 to 7 show a semiconductor device according to a first embodiment of the present disclosure. The semiconductor device A1 of the present embodiment includes a support 1, one or more first semiconductor elements 5A, and one or more first bonding sheets 6A. In the present embodiment, the semiconductor device A1 further includes one or more second semiconductor element 5B, one or more second bonding sheets 6B, a positive input terminal 7A, an output terminal 7B, a negative input terminal 7C, a plurality of control terminals 7D, a plurality of control terminals 7E, a plurality of first wires 8A, a plurality of second wires 8B, a plurality of third wires 8C, a plurality of fourth wires 8D, and a sealing resin 9.

The number of first semiconductor element 5A and the number of second semiconductor element 5B are not limited. In the present embodiment, the semiconductor device A1 includes a plurality of first semiconductor elements 5A and a plurality of second semiconductor elements 5B. The number of first bonding sheet 6A and the number of second bonding sheet 6B are not limited. In the present embodiment, the semiconductor device A1 includes a plurality of first bonding sheets 6A and a plurality of second bonding sheets 6B.

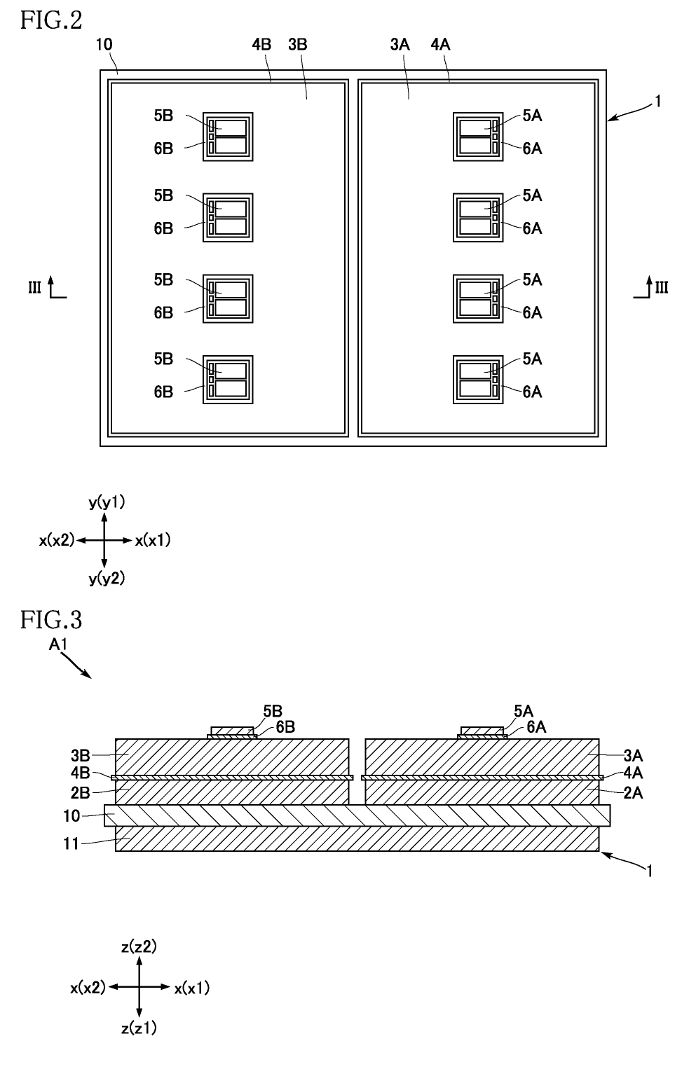

In FIGS. 1 to 7, the thickness direction of the support is defined as a first direction z of the present disclosure. A first side in the first direction z is referred to as a z1 side, and a second side opposite the first side in the first direction z is referred to as a z2 side. A direction orthogonal to the first direction z is defined as a second direction x. A first side in the second direction x is referred to as a x1 side, and a second side opposite the x1 side is referred to as a x2 side. The direction orthogonal to the first direction z and the second direction x is defined as a third direction y. A first side in the third direction y is referred to as a y1 side, and a second side opposite the y1 side is referred to as a y2 side. For ease of understanding, the positive input terminal 7A, the output terminal 7B, the negative input terminal 7C, the control terminals 7E and 7D, the first wires 8A, the second wires 8B, the third wires 8C, the fourth wires 8D, and the sealing resin 9 are omitted from FIGS. 2 to 7.

The specific applications of the semiconductor device A1 are not limited. In the semiconductor device A1, the first semiconductor elements 5A form an upper arm circuit while the second semiconductor elements 5B form a lower arm circuit, whereby a half-bridge circuit is formed. The semiconductor device A1 constitutes an inverter that converts DC power into AC power, for example, and supplies the power to a drive source, such as a motor. The semiconductor device A1 of the present embodiment will be described using an example having one half-bridge circuit, but it may be configured to supply power to a three-phase AC motor by having, for example, three half-bridge circuits.

The first semiconductor elements 5A and the second semiconductor elements 5B are made using a semiconductor material mainly composed of SiC (silicon carbide). The semiconductor material is not limited to SiC and may be Si (silicon), GaAs (gallium arsenide), or GaN (gallium nitride), for example. In the present embodiment, the first semiconductor elements 5A and the second semiconductor elements 5B are MOSFETs (Metal-Oxide-Semiconductor Field Effect Transistors). The first semiconductor elements 5A and the second semiconductor elements 5B are not limited to MOSFETs, but maybe field-effect transistors including MISFETs (Metal-Insulator-Semiconductor FETs), bipolar transistors such as IGBTs (Insulated Gate Bipolar Transistors), IC chips such as LSIs, diodes, capacitors, and the like.

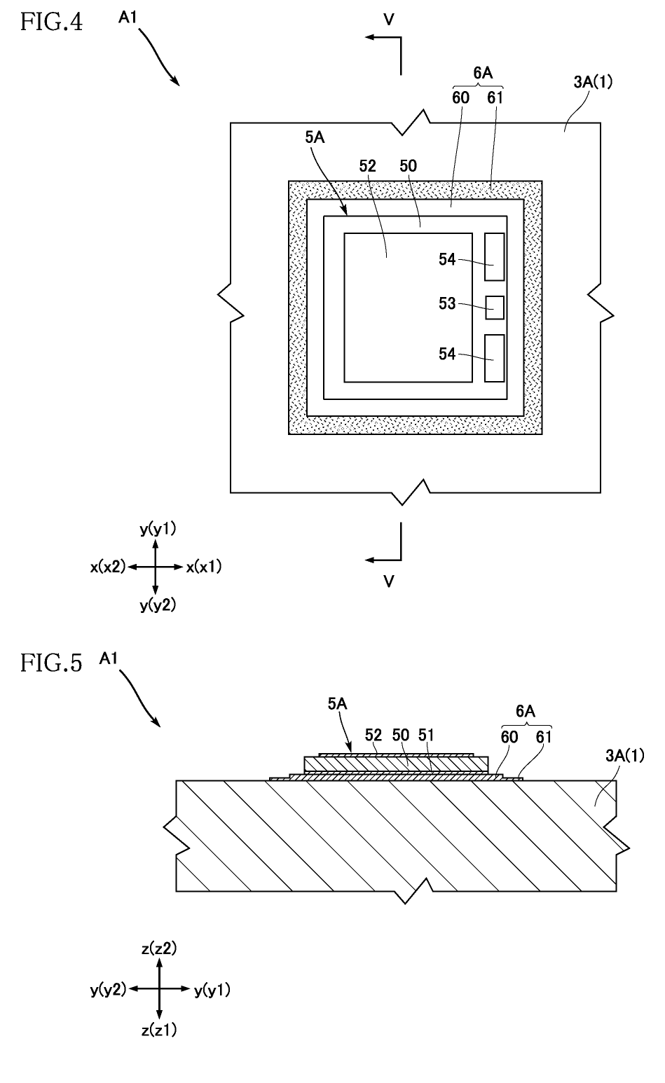

As shown in FIGS. 4 to 7, the first and the second semiconductor elements 5A and 5B each include an element body 50, a drain electrode 51, a source electrode 52, a gate electrode 53, and a source sense electrode 54. The element body 50 is made of the semiconductor material described above. The drain electrode 51 is disposed on the z1 side of the element body 50 in the first direction z. The source electrode 52, the gate electrode 53, and the source sense electrode 54 are disposed on the z2 side of the element body 50 in the first direction z.

As shown in FIG. 3, the support 1 has an insulating layer 10, a reverse-surface electrode layer 11, a first obverse-surface electrode layer 2A, a second obverse-surface electrode layer 2B, a third obverse-surface electrode layer 3A, a fourth obverse-surface electrode layer 3B, a bonding layer 4A, and a bonding layer 4B.

The insulating layer 10 is an insulating plate-like member containing ceramic, for example. The reverse-surface electrode layer 11 is laminated on the z1 side of the insulating layer 10 in the first direction z. The reverse-surface electrode layer 11 contains a metal such as Cu (copper), for example. The first obverse-surface electrode layer 2A is laminated on the z2 side of the insulating layer 10 in the first direction z and on the x1 side in the second direction x. The second obverse-surface electrode layer 2B is laminated on the z2 side of the insulating layer 10 in the first direction z and on the x2 side in the second direction x. The first obverse-surface electrode layer 2A and the second obverse-surface electrode layer 2B are spaced apart from each other and each contain a metal such as Cu (copper), for example. The insulating layer 10, the reverse-surface electrode layer 11, the first obverse-surface electrode layer 2A, and the second obverse-surface electrode layer 2B may form a DBC (Direct Bonded Copper) substrate or an AMB(Active Metal Brazing) substrate.

The third obverse-surface electrode layer 3A is bonded to the first obverse-surface electrode layer 2A via the bonding layer 4A. The third obverse-surface electrode layer 3A contains a metal such as Cu (copper), for example. The bonding layer 4A bonds the first obverse-surface electrode layer 2A and the third obverse-surface electrode layer 3A by solid-phase diffusion bonding, for example. The bonding layer 4A is not limited to any specific configuration and may, for example, be configured such that metal layers containing Ag (silver) are formed on opposite surfaces of a base layer containing Al (aluminum). In this case, a metal layer containing, for example, Ag (silver) may be formed on the surfaces of the first obverse-surface electrode layer 2A and the third obverse-surface electrode layer 3A.

The fourth obverse-surface electrode layer 3B is bonded to the second obverse-surface electrode layer 2B via the bonding layer 4B. The fourth obverse-surface electrode layer 3B contains a metal such as Cu (copper), for example. The bonding layer 4B bonds the second obverse-surface electrode layer 2B and the fourth obverse-surface electrode layer 3B by solid-phase diffusion bonding, for example. The bonding layer 4B is not limited to any specific configuration and may, for example, be configured such that metal layers containing Ag (silver) are formed on opposite surfaces of a base layer containing Al (aluminum). In this case, a metal layer containing, for example, Ag (silver) may be formed on the surfaces of the second obverse-surface electrode layer 2B and the fourth obverse-surface electrode layer 3B.

The first semiconductor elements 5A are conductively bonded to the third obverse-surface electrode layer 3A via the first bonding sheets 6A. In the present embodiment, the drain electrode 51 of each first semiconductor element 5A is conductively bonded to the third obverse-surface electrode layer 3A via a first bonding sheet 6A. The first bonding sheet 6A conductively bonds the first semiconductor element 5A and the third obverse-surface electrode layer 3A, for example, by solid-phase diffusion bonding. The specific configuration of the first bonding sheet 6A is not limited. When solid-phase diffusion bonding is used, the first bonding sheet 6A may, for example, be configured such that metal layers containing Ag (silver) are formed on opposite surfaces of a base layer containing Al (aluminum). In this case, a metal layer containing, for example, Ag

(silver) may be formed on the surfaces of the first semiconductor element 5A and the third obverse-surface electrode layer 3A. In this way, for example, the drain electrodes 51 of the first semiconductor elements 5A are electrically connected to the third obverse-surface electrode layer 3A. The first bonding sheet 6A is not limited to any specific shape and is rectangular in the illustrated example.

As shown in FIGS. 4 and 5, each first bonding sheet 6A includes a first portion 60 and a second portion 61. In FIG. 4, hatching is applied to the second portion 61 for ease of understanding, and the same applies to the subsequent figures. The first portion 60 has a part overlapping with the first semiconductor element 5A as viewed in the first direction z. The second portion 61 includes a part that does not overlap with the first semiconductor element 5A as viewed in the first direction z and is smaller in thickness in the first direction z than the first portion 60. The second portion 61 is a compression mark formed when the first bonding sheet 6A is temporarily bonded to the third obverse-surface electrode layer 3A (the support 1) during the manufacturing process of the semiconductor device A1, which will be described later.

The specific configurations of the first portion 60 and the second portion 61 are not limited. In the illustrated example, no part of the second portion 61 overlaps with the first semiconductor element 5A as viewed in the first direction z, and the second portion 61 is located outside the first semiconductor element 5A in the second direction x and the third direction y. The second portion 61 is in contact with the four edges of the first bonding sheet 6A. The second portion 61 is in contact with the four corners of the first bonding sheet 6A. The second portion 61 has the shape of a rectangular frame as viewed in the first direction z. The first portion 60 is spaced apart from all edges of the first bonding sheet 6A.

The second semiconductor element 5B are conductively bonded to the fourth obverse-surface electrode layer 3B via the second bonding sheets 6B. In the present embodiment, the drain electrode 51 of each second semiconductor element 5B is conductively bonded to the fourth obverse-surface electrode layer 3B via a second bonding sheet 6B. The second bonding sheet 6B conductively bonds the second semiconductor element 5B and the fourth obverse-surface electrode layer 3B, for example, by solid-phase diffusion bonding. The specific configuration of the second bonding sheet 6B is not limited. When solid-phase diffusion bonding is used, the second bonding sheet 6B may, for example, be configured such that metal layers containing Ag (silver) are formed on opposite surfaces of a base layer containing Al (aluminum). In this case, a metal layer containing, for example, Ag (silver) may be formed on the surfaces of the second semiconductor element 5B and the fourth obverse-surface electrode layer 3B. In this way, for example, the drain electrodes 51 of the second semiconductor elements 5B are electrically connected to the fourth obverse-surface electrode layer 3B. The second bonding sheet 6B is not limited to any specific shape and is rectangular in the illustrated example. The second bonding sheet 6B may have the same configuration as the first bonding sheet 6A, or may have a different configuration.

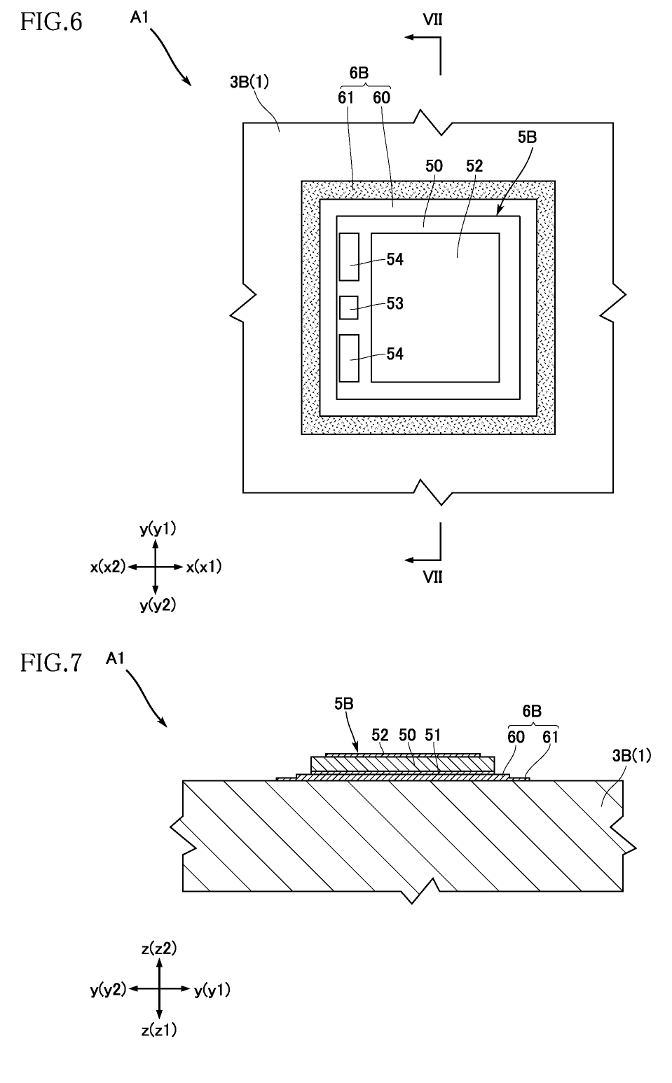

As shown in FIGS. 6 and 7, each second bonding sheet 6B includes a first portion 60 and a second portion 61. The first portion 60 has a part that overlaps with the second semiconductor element 5B as viewed in the first direction z. The second portion 61 includes a part that does not overlap with the second semiconductor element 5B as viewed in the first direction z and is smaller in thickness in the first direction z than the first portion 60. The second portion 61 is a compression mark formed when the second bonding sheet 6B is temporarily bonded to the fourth obverse-surface electrode layer 3B (the support 1) during the manufacturing process of the semiconductor device A1, which will be described later.

The specific configurations of the first portion 60 and the second portion 61 are not limited. In the illustrated example, no part of the second portion 61 overlaps with the second semiconductor element 5B as viewed in the first direction z, and the second portion 61 is located outside the second semiconductor element 5B in the second direction x and the third direction y. The second portion 61 is in contact with the four edges of the second bonding sheet 6B. The second portion 61 is in contact with the four corners of the second bonding sheet 6B. The second portion 61 has the shape of a rectangular frame as viewed in the first direction z. The first portion 60 is spaced apart from all edges of the second bonding sheet 6B.

The positive input terminal 7A is a terminal connected to the positive side of a DC power supply. The positive input terminal 7A is conductively bonded to the third obverse-surface electrode layer 3A.

The output terminal 7B is a terminal connected to the load side, such as a motor. The output terminal 7B is conductively bonded to the fourth obverse-surface electrode layer 3B.

The negative input terminal 7C is a terminal connected to the negative side of a DC power supply. The negative input terminal 7C is connected to, for example, the source electrodes 52 of the second semiconductor elements 5B via the second wires 8B. The second wires 8B contain a metal such as copper (Cu), aluminum (Al), or gold (Au), for example.

The source electrodes 52, for example, of the first semiconductor elements 5A are electrically connected to the fourth obverse-surface electrode layer 3B via the first wires 8A. The first wires 8A contain a metal such as copper (Cu), aluminum (Al), or gold (Au), for example.

The control terminals 7D are terminals for controlling the first semiconductor elements 5A. The control terminals 7D are electrically connected via the third wires 8C to, for example, the gate electrodes 53 or the source sense electrodes 54 of the first semiconductor elements 5A. The third wires 8C contain a metal such as copper (Cu), aluminum (Al), or gold (Au), for example.

The control terminals 7E are terminals for controlling the second semiconductor elements 5B. The control terminals 7E are electrically connected via the fourth wires 8D to, for example, the gate electrodes 53 or the source sense electrodes 54 of the second semiconductor elements 5B. The fourth wires 8D contain a metal such as copper (Cu), aluminum (Al), or gold (Au), for example.

The sealing resin 9 covers a part of the support 1, the first semiconductor elements 5A, and the second semiconductor elements 5B. The positive input terminal 7A, the output terminal 7B, the negative input terminal 7C, the control terminals 7D, and the control terminals 7E each protrude partially from the sealing resin 9.

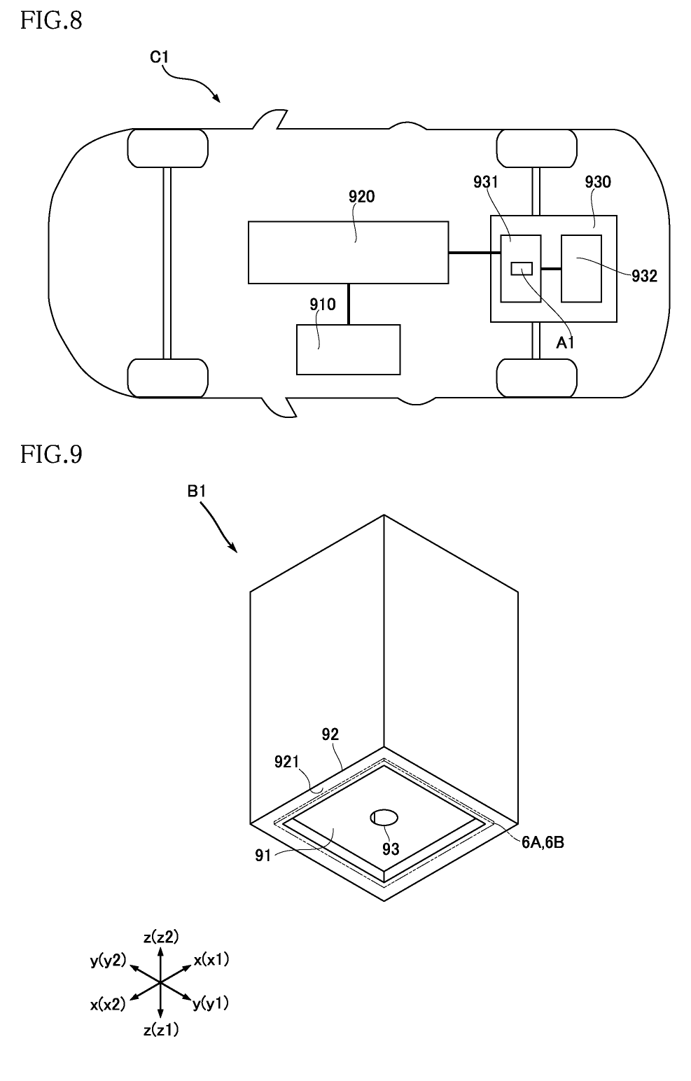

Next, a vehicle C1 equipped with the semiconductor device A1 will be described based on FIG. 8. The vehicle C1 may be, for example, an electric vehicle (EV).

As shown in FIG. 8, the vehicle C1 includes an on-board charger 910, a storage battery 920, and a drive system 930. The on-board charger 910 receives electric power wirelessly from a power supply facility (not shown) installed outdoors. Alternatively, power supply from the power supply facility to the on-board charger 910 may be performed via a wired connection. The on-board charger 910 includes a step-up DC-DC converter. The voltage of the power supplied to the on-board charger 910 is increased by the converter and then supplied to the storage battery 920. The increased voltage is, for example, 600 V.

The drive system 930 drives the vehicle C1. The drive system 930 has an inverter 931 and a driving source 932. The semiconductor device A1 constitutes a part of the inverter 931. The power stored in the storage battery 920 is supplied to the inverter 931. The power supplied from the storage battery 920 to the inverter 931 is a DC power. Unlike the power system shown in FIG. 8, a step-up DC-DC converter may be additionally provided between the storage battery 920 and the inverter 931. The inverter 931 converts DC power into AC power. The inverter 931 including the semiconductor device A1 is electrically connected to the driving source 932.

The driving source 932 has an AC motor and a transmission. When the AC power converted by the inverter 931 is supplied to the driving source 932, the AC motor rotates, and the rotation is transmitted to the transmission. The transmission appropriately reduces the rotation speed transmitted from the AC motor and rotates the drive shaft of the vehicle C1. Thus, the vehicle C1 is driven. When driving the vehicle C1, it is necessary to freely control the rotation speed of the AC motor based on the information such as the amount of movement of the accelerator pedal. The semiconductor device A1 in the inverter 931 is necessary to output the AC power with a frequency corresponding to the required rotation speed of the AC motor.

Next, a method for manufacturing the semiconductor device A1 will be described.

FIGS. 9 to 13 show a holder B1 used in the manufacturing method of the semiconductor device A1. The holder B1 is used for holding and temporarily bonding the first bonding sheet 6A or the second bonding sheet 6B in the manufacturing method of the semiconductor device A1.

The material of the holder B1 is not limited and may be, for example, metal or resin.

The holder B1 has, for example, a main surface 91, a protrusion 92, and a suction hole 93.

The main surface 91 faces the z1 side in the first direction z. The protrusion 92 protrudes from the main surface 91 to the z1 side in the first direction z. The number and shape of protrusion 92 are not limited. In the illustrated example, the holder B1 has one protrusion 92. The protrusion 92 has the shape of a rectangular frame as viewed in the first direction z. The number and shape of protrusion 92 correspond to the configuration of the second portion 61 of the first bonding sheet 6A and the second bonding sheet 6B, described later.

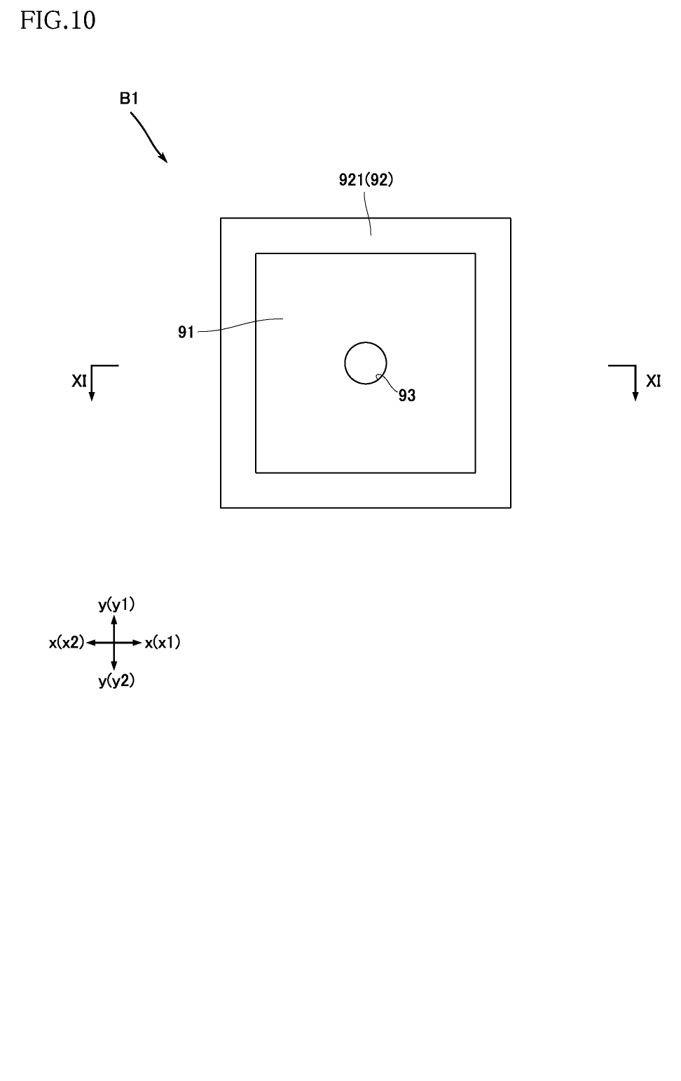

The protrusion 92 has a contact surface 921. The contact surface 921 faces the z1 side in the first direction z. The contact surface 921 is located on the z1 side in the first direction z relative to the main surface 91. The shape and size of contact surface 921 are not limited, and various shapes such as rectangular, circular, elliptical, or polygonal shapes may be selected. In the example shown in FIGS. 9 and 10, the contact surface 921 has the shape of a rectangular frame. In the illustrated example, the width of the contact surface 921 is, for example, at least 0.1 mm and at most 2 mm.

The suction hole 93 is open in the main surface 91. The suction hole 93 is not limited to any specific shape. In the illustrated example, the suction hole 93 is circular as viewed in the first direction z. The number of suction hole 93 is not limited. The holder B1 may have one suction hole 93 or may have a plurality of suction holes 93.

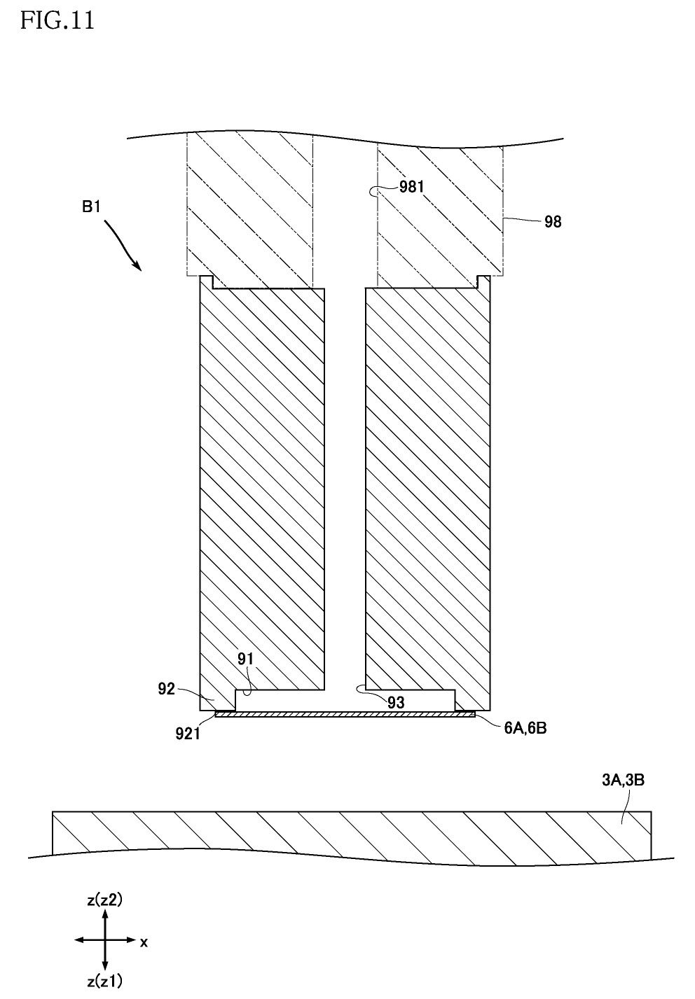

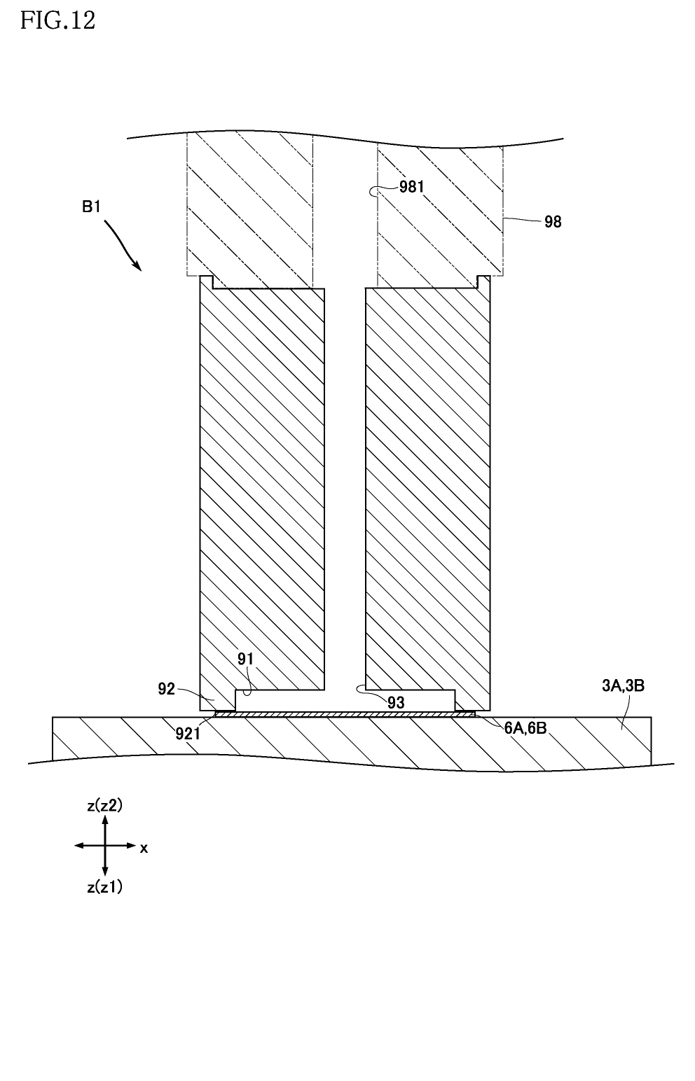

As shown in FIGS. 11 and 12, in the illustrated example, the holder B1 is attached, for example, to a base 98. The base 98 functions to apply a suction force necessary for holding the holder B1 and move the holder B1 to a desired position. In the illustrated example, the base 98 has a suction port 981. The suction port 981 is connected to the suction hole 93. Negative pressure is created near the suction hole 93 by sucking gas through the suction port 981. The negative pressure is used to hold the first bonding sheet 6A or the second bonding sheet 6B against the contact surface 921.

In the manufacturing method of the semiconductor device A1, the first semiconductor elements 5A are conductively bonded to the third obverse-surface electrode layer 3A, and the second semiconductor elements 5B are conductively bonded to the fourth obverse-surface electrode layer 3B. In the present embodiment, such conductive bonding is performed by solid-phase diffusion bonding. The first bonding sheets 6A and the second bonding sheets 6B are used to more appropriately achieve the solid-phase diffusion bonding.

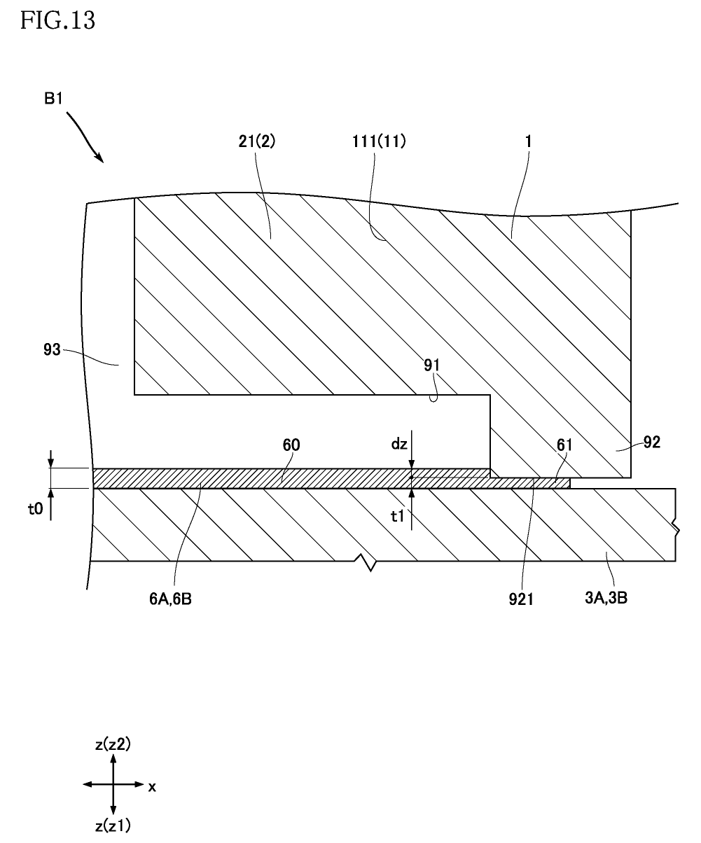

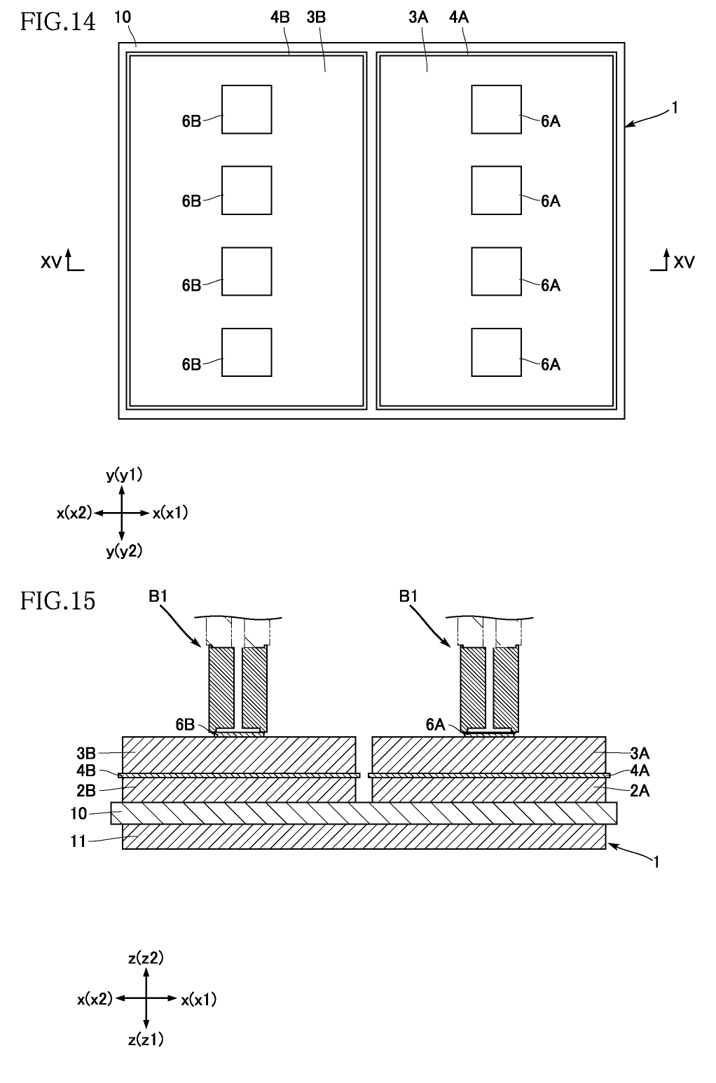

As shown in FIGS. 14 and 15, the support 1 is prepared. Next, by using the holder B1, the first bonding sheets 6A are temporarily bonded to the third obverse-surface electrode layer 3A, and the second bonding sheets 6B are temporarily bonded to the fourth obverse-surface electrode layer 3B. The first bonding sheets 6A and the second bonding sheets 6B are formed as metal foils. By way of example, each bonding sheet has, for example, a size of at least 2 mm square and at most 15 mm square in plan view as viewed in the first direction z, and a thickness in the first direction z (the thickness t0 in FIG. 13) of at least 0.05 mm and at most 0.3 mm, for example approximately 0.11 mm.

The first bonding sheet 6A or the second bonding sheet 6B, disposed at a predetermined position outside the figure, is held with the holder B1 as shown in FIG. 11. The first bonding sheet 6A or the second bonding sheet 6B is held in contact with the contact surface 921 by the negative pressure applied through the suction hole 93.

Next, the holder B1 is moved above the third obverse-surface electrode layer 3A or the fourth obverse-surface electrode layer 3B to which the first bonding sheet 6A or the second bonding sheet 6B is to be temporarily bonded. The holder B1 is then moved toward the z1 side in the first direction z. As a result of the downward movement, the first bonding sheet 6A or the second bonding sheet 6B comes into contact with the third obverse-surface electrode layer 3A or the fourth obverse-surface electrode layer 3B as shown in FIG. 12.

When the holder B1 is further pressed toward the z1 side in the first direction z by the base 98, a portion of the first bonding sheet 6A or the second bonding sheet 6B is crushed by the pressing force applied by the contact surface 921 as shown in FIG. 13. This crushed portion is a compression mark, which becomes the second portion 61. The thickness t1 of the second portion 61 is smaller than the above-mentioned thickness t0 by the height dz.

By the pressing force applied by the contact surface 921, the first bonding sheet 6A or the second bonding sheet 6B is temporarily bonded to the third obverse-surface electrode layer 3A or the fourth obverse-surface electrode layer 3B. Although this bonding has lower bonding strength compared with, for example, solid-phase diffusion bonding, it prevents the first bonding sheets 6A and the second bonding sheets 6B from moving during the subsequent steps, such as transporting the support 1. In addition to to the pressing force applied by the contact surface 921, ultrasonic waves, heating, or the like may further be applied to perform temporary bonding.

After the first bonding sheets 6A and the second bonding sheets 6B are temporarily bonded, the first semiconductor elements 5A and the second semiconductor elements 5B are placed or temporarily bonded onto the first bonding sheets 6A and the second bonding sheets 6B as shown in FIGS. 1 and 2. In this process, the first semiconductor elements 5A and the second semiconductor elements 5B are placed or temporarily bonded onto the first portions 60 of corresponding ones of the first bonding sheets 6A and the second bonding sheets 6B. Specifically, the first semiconductor elements 5A and the second semiconductor elements 5B are positioned so as to overlap with at least parts of the first portions 60 of corresponding ones of the first bonding sheets 6A and the second bonding sheets 6B as viewed in the first direction z. Also, the first semiconductor elements 5A and the second semiconductor elements 5B are positioned so as not to overlap with at least parts of the second portions 61 of corresponding ones of the first bonding sheets 6A and the second bonding sheets 6B as viewed in the first direction z. In the illustrated example, as viewed in the first direction z, each of the first semiconductor elements 5A and the second semiconductor elements 5B entirely overlaps with the first portion 60 and does not overlap at all with the second portion 61.

Subsequently, solid-phase diffusion bonding, for example, is performed to the integrated assembly made up of the support 1, the first and the second bonding sheets 6A and 6B, and the first and the second semiconductor elements 5A and 5B as shown in FIGS. 1 and 2. Thus, the first semiconductor elements 5A and the second semiconductor elements 5B are conductively bonded to the third obverse-surface electrode layer 3A and the fourth obverse-surface electrode layer 3B via the first bonding sheets 6A and the second bonding sheets 6B. Thereafter, fixation of the positive input terminal 7A, the output terminal 7B, the negative input terminal 7C, the control terminals 7D and the control terminals 7E, connection of the first wires 8A, the second wires 8B, the third wires 8C and the fourth wires 8D, and formation of the sealing resin 9 are performed, whereby the semiconductor device A1 is manufactured.

Next, the effects of the semiconductor device A1 and the manufacturing method of the semiconductor device A1 will be described.

As shown in FIG. 13, the second portion 61 of the first bonding sheet 6A is a compression mark formed, for example, by being pressed by the contact surface 921 of the holder B1. On the other hand, the first portion 60 is a non-pressed portion where no pressure is applied by the contact surface 921for example. The thickness t1 of the second portion 61 in the first direction z is smaller than the thickness t0 of the first portion 60. Therefore, if, for example, solid-phase diffusion bonding is performed with the first semiconductor element 5A superimposed on the second portion 61, there is a risk of bonding failure occurring. Also, when ultrasonic waves are applied or heating is performed during the temporary bonding of the first bonding sheet 6A, the surface of the second portion 61 may be damaged or its crystal structure may be changed. In such a case again, the second portion 61 may cause a bonding failure. In the present embodiment, the second portion 61 has a part that is spaced apart from the first semiconductor element 5A as viewed in the first direction z. Therefore, bonding failures caused by the second portion 61 can be suppressed, and the first semiconductor element 5A can be more appropriately bonded .

In the present embodiment, the entirety of the second portion 61 is spaced apart from the first semiconductor element 5A. The first semiconductor element 5A overlaps entirely with the first portion 60 and does not overlap with the second portion 61. This is favorable for the bonding of the first semiconductor element 5A.

The second portion 61 is in contact with the edges of the first bonding sheet 6A and located along the end edges. Thus, when the first bonding sheet 6A is temporarily bonded to the third obverse-surface electrode layer 3A, the edge and the area near the edge of the first bonding sheet 6A are temporarily bonded to the third obverse-surface electrode layer 3A. Therefore, it is possible to suppress the temporality bonded first bonding sheet 6A from peeling off from the third obverse-surface electrode layer 3A due to insufficient bonding. The second portion 61 is in contact with the corners of the first bonding sheet 6A. This further suppresses peeling of the first bonding sheet 6A.

Similar to the improved bonding of the first semiconductor element 5A because of the configuration of the first portion 60 and the second portion 61 of the first bonding sheet 6A, improved bonding of the second semiconductor element 5B can be expected because of the configuration of the first portion 60 and the second portion 61 of the second bonding sheet 6B.

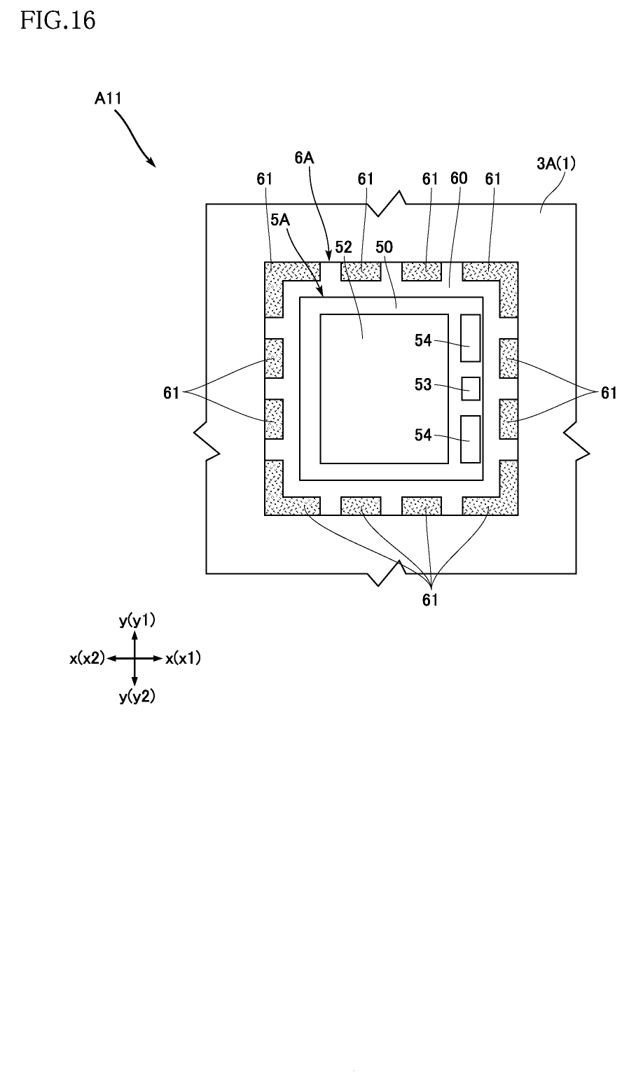

FIGS. 16 to 26 show variations and other embodiments of the present disclosure. In these figures, the elements that are identical or similar to those of the above embodiment are denoted by the same reference signs as those used for the above embodiment. Various parts of variations and embodiments may be selectively used in any appropriate combination as long as it is technically compatible.

### First embodiment, first variation:

FIG. 16 shows a first variation of the semiconductor device A1. The figure shows the region where the first semiconductor element 5A is bonded to the third obverse-surface electrode layer 3A via the first bonding sheet 6A. However, the illustrated configuration may also be applied to the region where the second semiconductor element 5B is bonded to the fourth obverse-surface electrode layer 3B via the second bonding sheet 6B. The same applies to the subsequent variations.

In the semiconductor device A11 of the present variation, the first bonding sheet 6A has a plurality of second portions 61. The second portions 61 are located along the edges of the first bonding sheet 6A and in contact with the edges of the first bonding sheet 6A. Four second portions 61 are in contact with the four corners of the first bonding sheet 6A. A part of the first portion 60 is interposed between two adjacent second portions 61. The first portion 60 is in contact with the edges of the first bonding sheet 6A. In other words, the second portions 61 of the present variation correspond to a configuration where the second portion 61 of the semiconductor device A1 is formed in a segmented strip pattern.

According to the present variation again, the first semiconductor element 5A can be more appropriately bonded. As understood from the present variation, the first bonding sheet 6A may have a plurality of second portions 61.

### First embodiment, second variation:

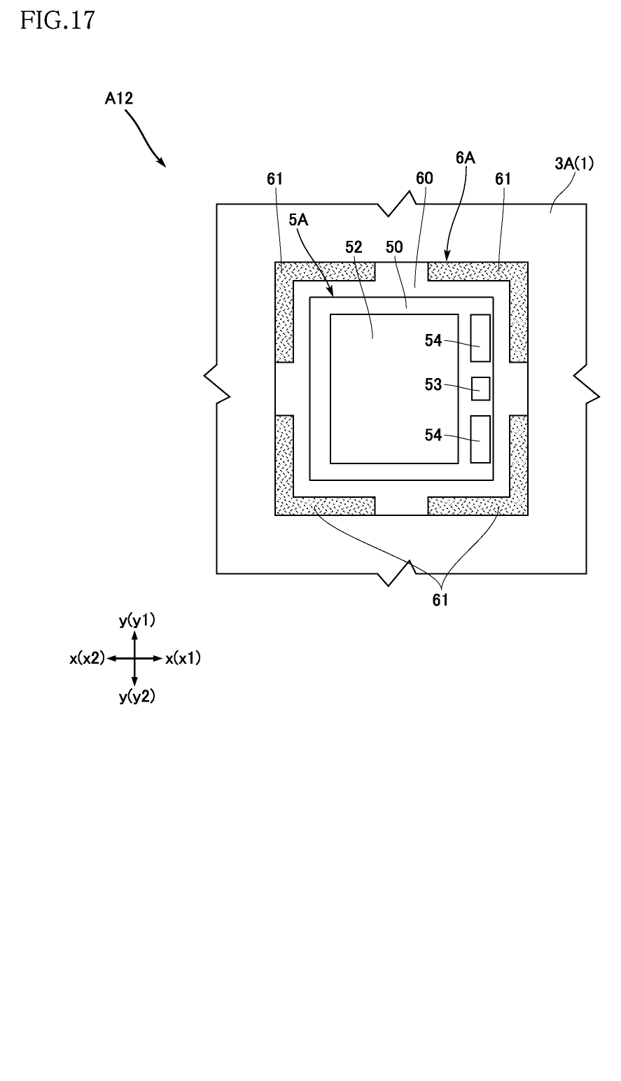

FIG. 17 shows a second variation of the semiconductor device A1. In the semiconductor device A12 of the present variation, the first bonding sheet 6A has four second portions 61. The four second portions 61 are in contact with the four corners of the first bonding sheet 6A. A part of the first portion 60 is interposed between two adjacent second portions 61.

According to the present variation again, the first semiconductor element 5A can be more appropriately bonded. As understood from the present variation, the first bonding sheet 6A may have a plurality of second portions 61.

### First embodiment, third variation:

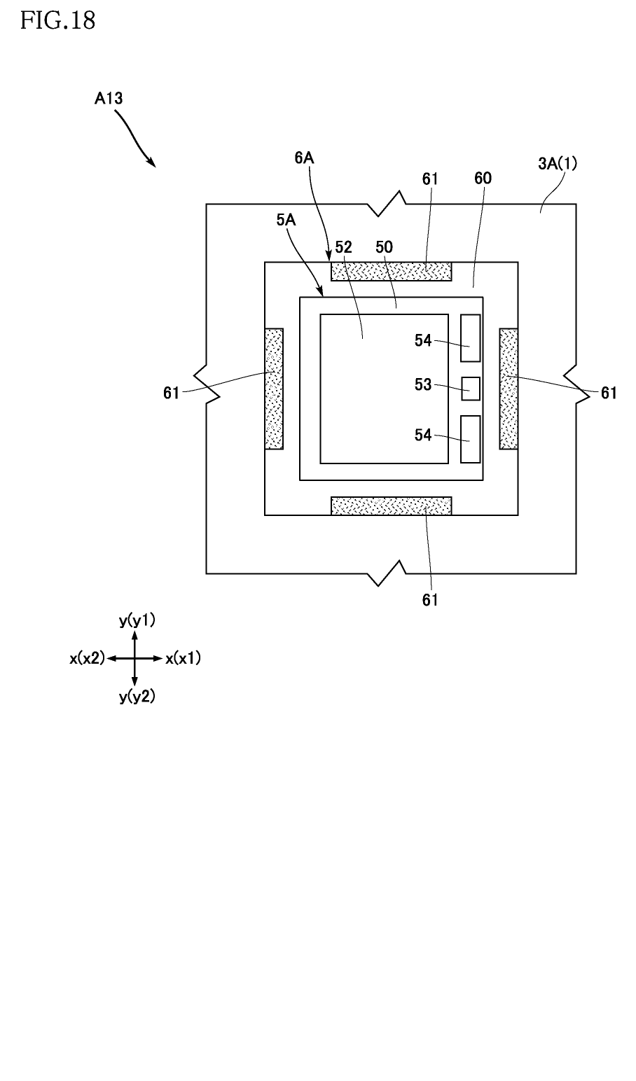

FIG. 18 shows a third variation of the semiconductor device A1. In the semiconductor device A13 of the present variation, the first bonding sheet 6A has a plurality of second portions 61. The second portions 61 are in contact with the edges of the first bonding sheet 6A. The second portions 61 are spaced apart from the corners of the first bonding sheet 6A. In the present variation, the four second portions 61 are positioned so as to be individually in contact with the central portions of the four edges of the first bonding sheet 6A.

According to the present variation again, the first semiconductor element 5A can be more appropriately bonded. As understood from the present variation, the second portion 61 may be spaced apart from the corners of the first bonding sheet 6A.

### Second embodiment:

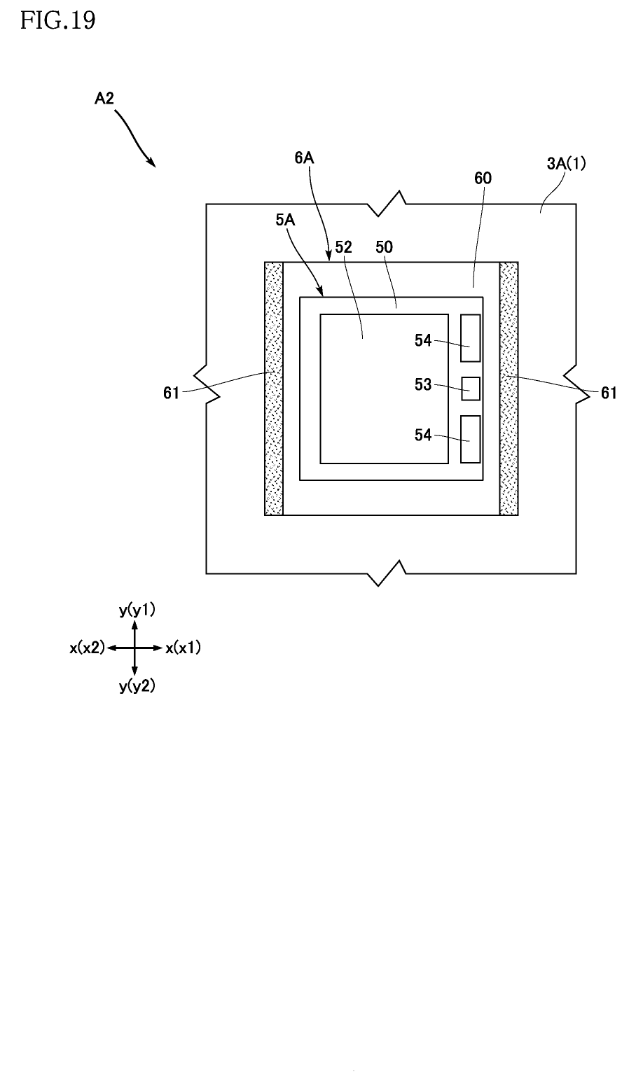

FIG. 19 shows a semiconductor device according to a second embodiment of the present disclosure. In the semiconductor device A2 of the present variation, the first bonding sheet 6A has two second portions 61. The two second portions 61 are individually in contact with two mutually parallel edges of the first bonding sheet 6A which are spaced apart from each other in the second direction x and extend in the third direction y. The two second portions 61 are in contact with the four corners of the first bonding sheet 6A.

According to the present variation again, the first semiconductor element 5A can be more appropriately bonded. As understood from the present embodiment, the number of second portion 61 is not limited. By arranging the two second portions 61 on opposite sides of the first bonding sheet 6A in the second direction x, the first bonding sheet 6A can be temporarily bonded in a more balanced manner.

### Second embodiment, first variation:

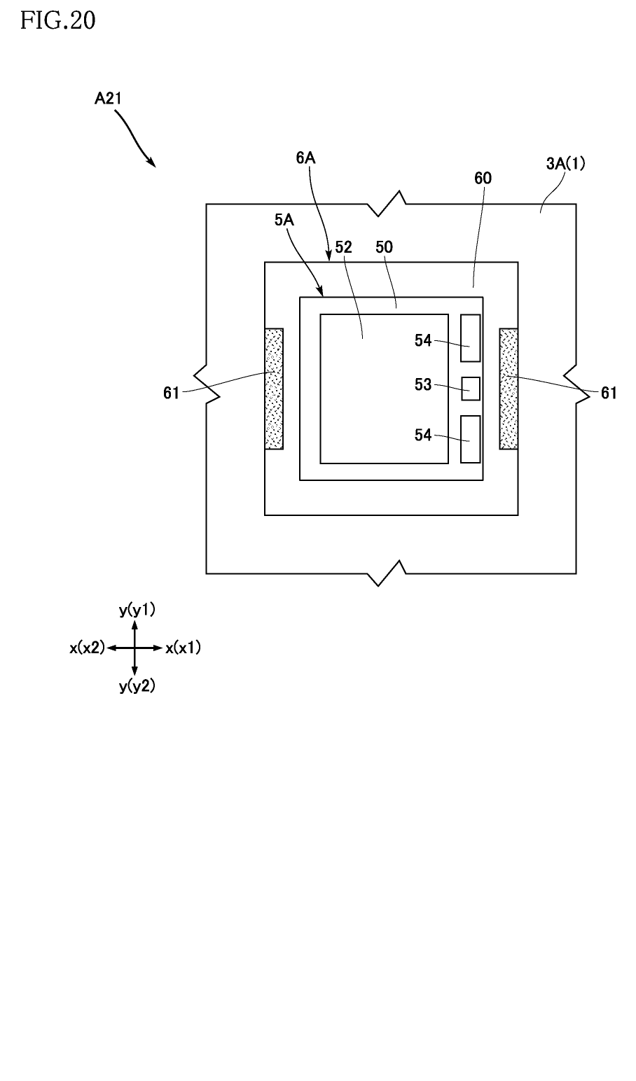

FIG. 20 shows a first variation of the semiconductor device A2. In the semiconductor device A21 of the present variation, the first bonding sheet 6A has two second portions 61. The two second portions 61 are individually in contact with two mutually parallel edges of the first bonding sheet 6A which are spaced apart from each other in the second direction x and extend in

the third direction y. The two second portions 61 are spaced apart from the four corners of the first bonding sheet 6A.

According to the present variation again, the first semiconductor element 5A can be more appropriately bonded. As understood from the present variation, the second portion 61 may be spaced apart from the corners of the first bonding sheet 6A.

### Third embodiment:

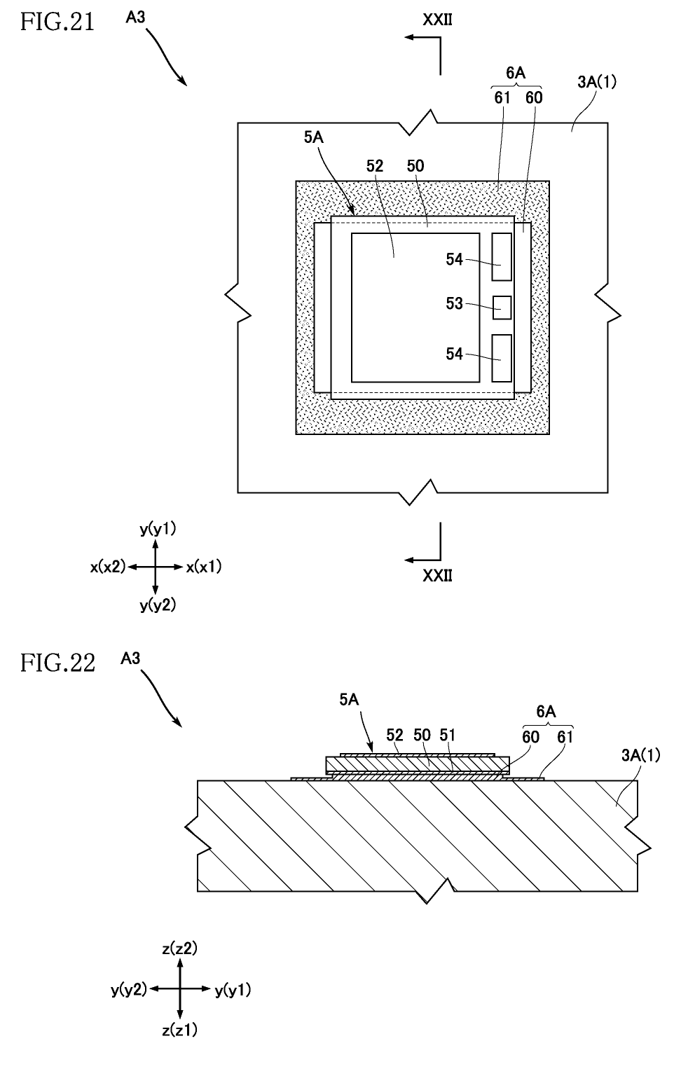

FIGS. 21 and 22 show a semiconductor device according to a third embodiment of the present disclosure. In the semiconductor device A3 of the present embodiment, the second portion 61 has a part that overlaps with the first semiconductor element 5A and a part that does not overlap with the first semiconductor element 5A as viewed in the first direction z.

In the illustrated example, the second portion 61 has the shape of a rectangular frame as viewed in the first direction z. Of the second portion 61, portions of two parts extending along the second direction x overlap with the first semiconductor element 5A as viewed in the first direction z. Unlike the illustrated example, only one of the two parts extending along the second direction x may overlap with the first semiconductor element 5A as viewed in the first direction z.

According to the present variation again, the first semiconductor element 5A can be more appropriately bonded. As understood from the present embodiment, a part of the second portion 61 may overlap with the first semiconductor element 5A. The first semiconductor element 5A can be appropriately bonded by limiting the part of the second portion 61 that overlaps with the first semiconductor element 5A to a small area.

### Third embodiment, first variation:

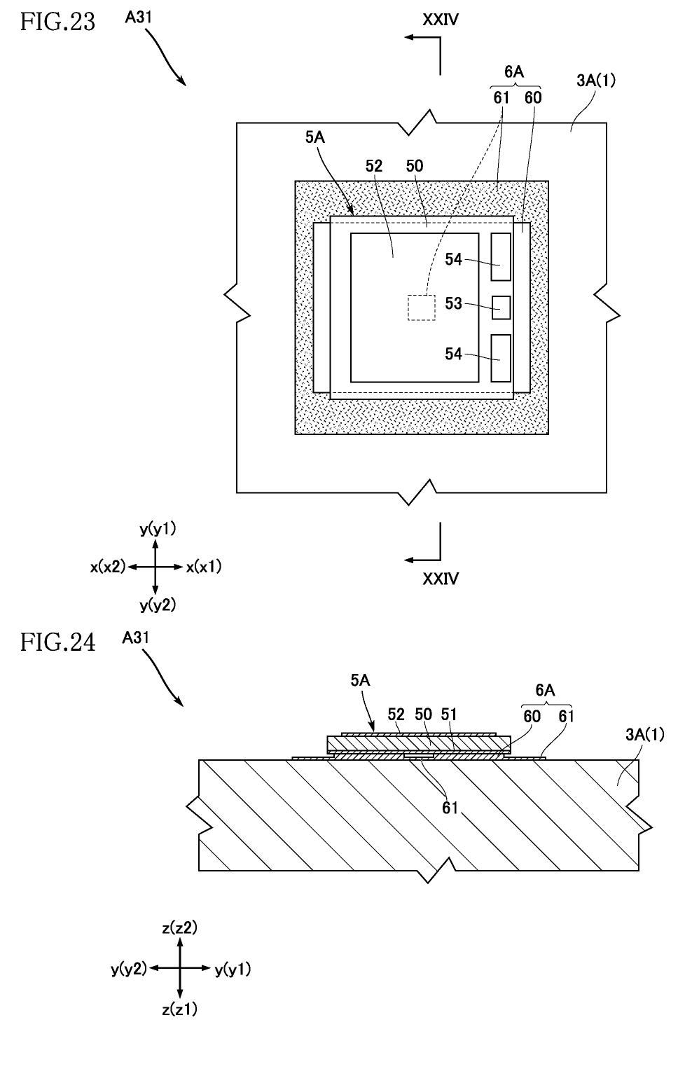

FIGS. 23 and 24 show a first variation of the semiconductor device A3. In the semiconductor device A31 of the present variation, the first bonding sheet 6A has two second portions 61. One of the second portions 61 has the same configuration as the second portion 61 of the semiconductor device A3. The other second portion 61 entirely overlaps with the first semiconductor element 5A as viewed in the first direction z. This second portion 61 is smaller in size compared with the second portion 61 having a rectangular frame shape. This second portion 61 may overlap with the center of the first semiconductor element 5A as viewed in the first direction z.

According to the present variation again, the first semiconductor element 5A can be more appropriately bonded. As understood from the present embodiment, the configuration in which the second portion 61 and the first semiconductor element 5A overlap with each other can be set in various ways.

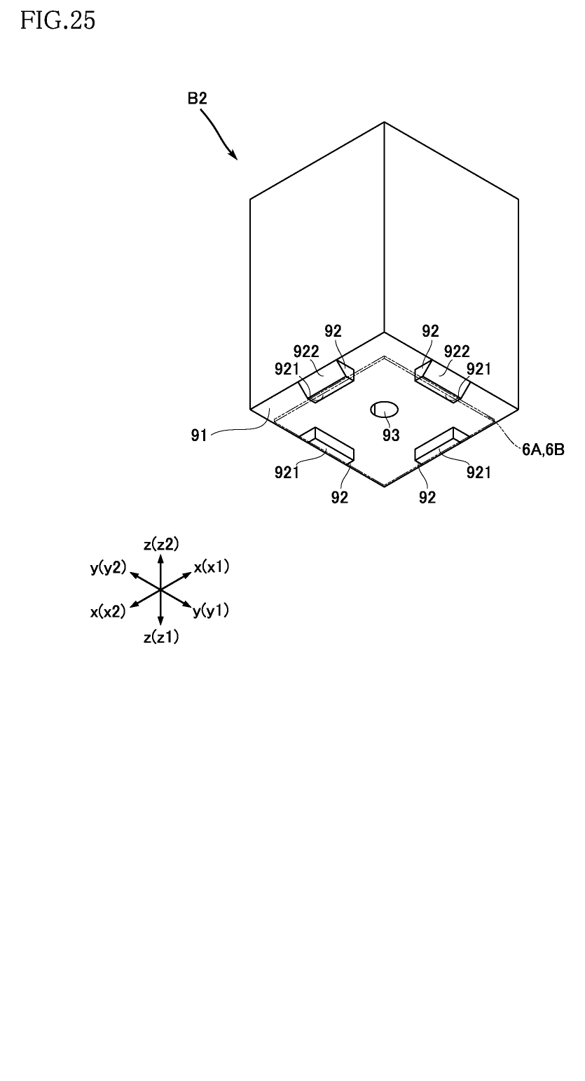

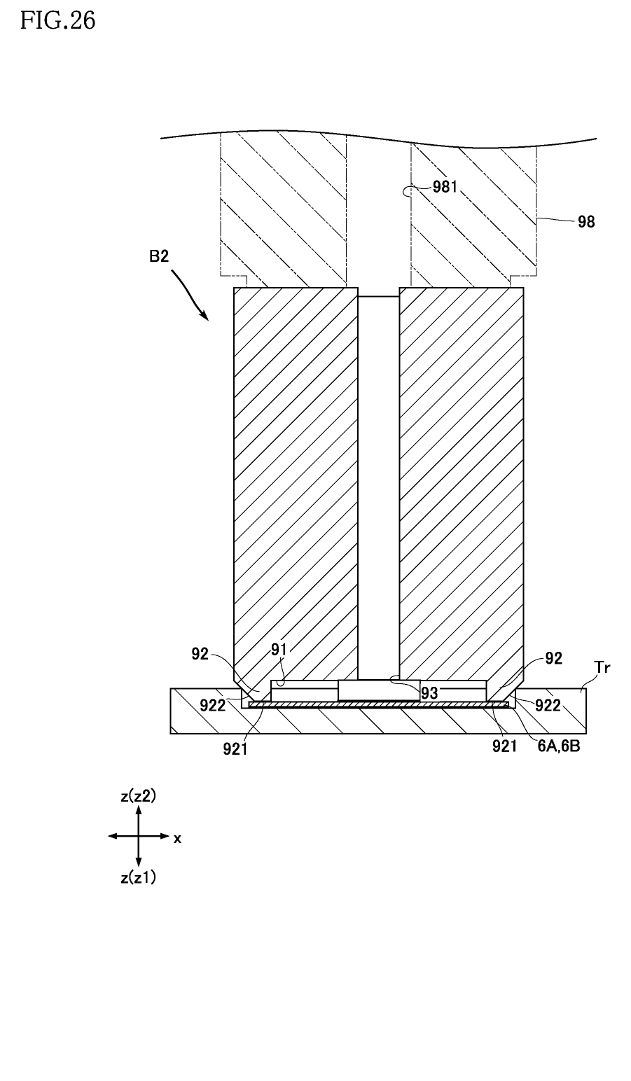

FIGS. 25 and 26 show other examples of the holder used in the manufacturing method of the semiconductor device of the present disclosure. The holder B2 of the present example has four protrusions 92. The holder B2 is configured to enable, for example, temporary bonding of the first bonding sheet 6A of the semiconductor device A13 shown in FIG. 18.

The protrusion 92 of the present variation has a contact surface 921 and an inclined surface 922. The contact surface 921 has the configuration described above. The inclined surface 922 is located outside the contact surface 921 in the second direction x or the third direction y. The inclined surface 922 is inclined so as to shift toward the z2 side in the first direction z as proceeding outward in the second direction x or the third direction y.

With the holder B2, temporary bonding of, for example, the first bonding sheet 6A of the semiconductor device A13 shown in FIG. 18 is possible. As shown in FIG. 26, because of the provision of the inclined surface 922, the holder B2 is prevented from interfering with the tray Tr when holding the first bonding sheet 6A or the second bonding sheet 6B placed in the recess of the tray Tr.

The semiconductor device and the manufacturing method of the semiconductor device according to the present disclosure are not limited to the embodiments described above. Various modifications in design may be made freely in the specific structure of the semiconductor device and the manufacturing method of the semiconductor device according to the present disclosure.

Clause 1. A semiconductor device (A1) comprising: a support (1); a first semiconductor element (5A) supported on the support (1); and a first bonding sheet (6A) interposed between the support (1) and the first semiconductor element (5A),

wherein the first bonding sheet (6A) includes a first portion (60) and a second portion (61), the first portion including a part that overlaps with the first semiconductor element (5A) as viewed in a first direction (z) that is a thickness direction of the support (1), the second portion including a part that does not overlap with the first semiconductor element (5A) as viewed in the first direction (z), the second portion being smaller in thickness in the first direction (z) than the first portion.

Clause 2. The semiconductor device (A1) according to clause 1, wherein no part of the second portion (61) overlaps with the first semiconductor element (5A) as viewed in the first direction (z).

Clause 3. The semiconductor device (A1) according to clause 1 or 2, wherein the first bonding sheet (6A) is rectangular as viewed in the first direction (z).

Clause 4. The semiconductor device (A2) according to clause 3, wherein the second portion (61) is in contact with two mutually parallel edges of the first bonding sheet (6A).

Clause 5. The semiconductor device (A1) according to clause 3, wherein the second portion (61) is in contact with all edges of the first bonding sheet (6A).

Clause 6. The semiconductor device (A1) according to clause 5, wherein the second portion (61) has a shape of a rectangular frame as viewed in the first direction (z).

Clause 7. The semiconductor device (A1) according to clause 3, wherein the second portion (61) is in contact with a corner of the first bonding sheet (6A).

Clause 8. The semiconductor device (A11) according to clause 3, wherein the second portion (61) is spaced apart from a corner of the first bonding sheet (6A).

Clause 9. The semiconductor device (A1) according to clause 1, wherein the second portion (61) includes a part overlapping with the first semiconductor element (5A) as viewed in the first direction (z).

Clause 10. The semiconductor device (A1) according to any one of clauses 1 to 9, wherein the first portion (60) is in contact with an edge of the first bonding sheet (6A).

Clause 11. The semiconductor device (A1) according to any one of clauses 1 to 10, wherein the first bonding sheet (6A) includes a metal layer containing Ag (silver).

Clause 12. The semiconductor device (A1) according to clause 11, wherein the first bonding sheet (6A) includes a base layer containing Al (aluminum).

Clause 13. The semiconductor device (A1) according to any one of clauses 1 to 12, wherein the support (1) includes a third obverse-surface electrode layer (3A), and the first semiconductor element (5A) is bonded to the third obverse-surface electrode layer (3A) via the first bonding sheet (6A).

Clause 14. A method for manufacturing a semiconductor device (A1), the method comprising the steps of:

temporarily bonding a first bonding sheet (6A) to a support (1); and bonding a first semiconductor element (5A) to the support (1) via the first bonding sheet (6A), wherein

the step of temporarily bonding the first bonding sheet (6A) includes forming a first portion (60) and a second portion (61) in the first bonding sheet (6A) by pressing a portion of the first bonding sheet (6A) toward the support (1) in the first direction (z), the first portion (60) being a non-pressed portion, the second portion being thinner in a thickness in the first direction (z) than the first portion (60) as a result of being pressed, and

the step of bonding the first semiconductor element (5A) is performed such that, as viewed in the first direction (z), the first semiconductor element (5A) overlaps with at least a part of the first portion (60) while the first semiconductor element (5A) does not overlap with at least a part of the second portion (61).

Clause 15. The method for manufacturing the semiconductor device (A1) according to clause 14, wherein the step of bonding the first semiconductor element (5A) employs solid-phase diffusion bonding.

Clause 16. A vehicle (C1) comprising:

a driving source (932); and the semiconductor device (A1) as set forth in any one of clauses 1 to 13, wherein the semiconductor device (A1) is electrically connected to the driving source (932).

### REFERENCE NUMERALS

A1, A11, A12, A13, A2, A21, A3, A31: Semiconductor device 1: Support 2A: First obverse-surface electrode layer 2B: Second obverse-surface electrode layer 3A: Third obverse-surface electrode layer 3B: Fourth obverse-surface electrode layer 4A: Bonding layer 4B: Bonding layer 5A: First semiconductor element 5B: Second semiconductor element 6A: First bonding sheet 6B: Second bonding sheet 7A: Positive input terminal 7B: Output terminal 7C: Negative input terminal 7D: Control terminal 7E: Control terminal 8A: First wire 8B: Second wire 8C: Third wire 8D: Fourth wire 9: Sealing resin 10: Insulating layer 11: Reverse-surface electrode layer 50: Element body 51: Drain electrode 52: Source electrode 53: Gate electrode 54: Source sense electrode 60: First portion 61: Second portion 91: Obverse surface 92: Protrusion 93: Suction hole 98: Base 910: On-board charger 920: Storage battery 921: Contact surface 922: Inclined surface 930: Drive system 931: Inverter 932: Driving source 981: Suction port B1, B2: Holder C1: Vehicle Tr: Tray dz: Height t0, t1: Thickness x: Second direction y: Third direction z: First direction

1. A semiconductor device comprising:
a support;
a first semiconductor element supported on the support; and
a first bonding sheet interposed between the support and the first semiconductor element,
wherein the first bonding sheet includes a first portion and a second portion, the first portion including a part that overlaps with the first semiconductor element as viewed in a first direction that is a thickness direction of the support, the second portion including a part that does not overlap with the first semiconductor element as viewed in the first direction, the second portion being smaller in thickness in the first direction than the first portion.

2. The semiconductor device according to claim 1, wherein no part of the second portion overlaps with the first semiconductor element as viewed in the first direction.

3. The semiconductor device according to claim 1, wherein the first bonding sheet is rectangular as viewed in the first direction.

4. The semiconductor device according to claim 3, wherein the second portion is in contact with two mutually parallel edges of the first bonding sheet.

5. The semiconductor device according to claim 3, wherein the second portion is in contact with all edges of the first bonding sheet.

6. The semiconductor device according to claim 5, wherein the second portion has a shape of a rectangular frame as viewed in the first direction.

7. The semiconductor device according to claim 3, wherein the second portion is in contact with a corner of the first bonding sheet.

8. The semiconductor device according to claim 3, wherein the second portion is spaced apart from a corner of the first bonding sheet.

9. The semiconductor device according to claim 1, wherein the second portion includes a part overlapping with the first semiconductor element as viewed in the first direction.

10. The semiconductor device according to claim 1, wherein the first portion is in contact with an edge of the first bonding sheet.

11. The semiconductor device according to claim 1, wherein the first bonding sheet includes a metal layer containing Ag.

12. The semiconductor device according to claim 11, wherein the first bonding sheet includes a base layer containing Al.

13. The semiconductor device according to claim 1, wherein the support includes a third obverse-surface electrode layer, and
the first semiconductor element is bonded to the third obverse-surface electrode layer via the first bonding sheet.

14. A method for manufacturing a semiconductor device, the method comprising the steps of:
temporarily bonding a first bonding sheet to a support; and
bonding a first semiconductor element to the support via the first bonding sheet, wherein
the step of temporarily bonding the first bonding sheet includes forming a first portion and a second portion in the first bonding sheet by pressing a portion of the first bonding sheet toward the support in the first direction, the first portion being a non-pressed portion, the second portion being thinner in a thickness in the first direction than the first portion as a result of being pressed, and
the step of bonding the first semiconductor element is performed such that, as viewed in the first direction, the first semiconductor element overlaps with at least a part of the first portion while the first semiconductor element does not overlap with at least a part of the second portion.

15. The method for manufacturing the semiconductor device according to claim 14, wherein the step of bonding the first semiconductor element employs solid-phase diffusion bonding.
